(19) United States
(12) Patent Application Publication
(10) Pub. No.: US 2026/0332112 A1
(43) Pub. Date: Oct. 22, 2026

(54) AMPLIFIER CIRCUIT WITH CONTROLLED POSITIVE FEEDBACK

(71) Applicant: Apple Inc., Cupertino, CA (US)

(72) Inventors: Bo SUN, Carlsbad, CA (US); Jafar SAVOJ, Menlo Park, CA (US); Sanjeev K. MAHESHWARI, Fremont, CA (US)

(21) Appl. No.: 19/180,915

(22) Filed: Apr. 16, 2025

(51) Int. Cl. H03F 3/45; G06F 1/08

(52) U.S. Cl. CPC H03F 3/45475; G06F 1/08

(57) ABSTRACT

An amplifier circuit with controlled positive feedback is disclosed. First and second amplifier circuits of the amplifier circuit may amplify respective signals of a differential signal to generate corresponding input signals. Third and fourth amplifier circuits of the amplifier circuit may amplify corresponding ones of the input signals to generate corresponding output signals. First and second feedback circuits included in the amplifier circuit may, based on respective voltage levels of the output signals, couple an output terminal of the third amplifier circuit to the input terminal of the fourth amplifier circuit, and couple an output terminal of the fourth amplifier circuit to an input of third amplifier circuit.

### FIELD

This disclosure relates to the field of integrated circuit implementation and, more particularly, to amplifier circuits.

### BACKGROUND

Computer systems typically include a number of interconnected integrated circuits. In some cases, the integrated circuits may communicate using communication channels or links to transmit and receive data symbols or bits. The communication channels may support parallel communication in which multiple data bits are transmitted in parallel, or serial communication in which data bits are transmitted one bit at a time in a serial fashion.

In the case of serial communication, some computer systems transmit serial data without a clock signal or other timing reference using a differential signal. As an integrated circuit receives such serial data, the integrated circuit may amplify the differential signal prior to performing clock recovery, in which a clock signal is generated using transitions in the received data. The resultant clock signal may then be used to sample the amplified differential signal in order to reconstruct the encoded data symbols or bits.

### BRIEF DESCRIPTION OF THE DRAWINGS

FIG. 1 is a block diagram depicting an embodiment of an amplifier circuit.

FIG. 2A is a block diagram depicting an embodiment of a feedback circuit for an amplifier circuit.

FIG. 2B is a block diagram depicting a different embodiment of a feedback circuit for an amplifier circuit.

FIG. 3A is a block diagram depicting an embodiment of a feedback circuit for an amplifier circuit that includes enable switches.

FIG. 3B is a block diagram depicting a different embodiment of a feedback circuit for an amplifier circuit that includes enable switches.

FIG. 4 is a block diagram of a computer system that includes two devices coupled to each other via a communication bus.

FIG. 5 is a flow diagram depicting an embodiment of a method for operating an amplifier circuit with controlled positive feedback.

FIG. 6 is a block diagram of an embodiment of a device that may include analog circuits.

FIG. 7 is a block diagram of various embodiments of computer systems that may include analog circuits.

FIG. 8 illustrates an example of a non-transitory computer-readable storage medium that stores circuit design information.

### DETAILED DESCRIPTION

Computer systems may include multiple circuit blocks configured to send and receive data via signals propagating on communication links or channels, which can employ different communication protocols. For example, two circuit blocks may transmit data to each other in a serial fashion using serializer/de-serializer (SERDES) circuits.

The electrical characteristics of the communication link can affect the quality of the signal at a receiver circuit coupled to the communication link. In some cases, a transmitter circuit may pre-distort a transmitted pulse in an attempt to correct for the electrical characteristics of the channel. In other cases, a receiver circuit can employ a variety of equalization techniques to improve signal quality before performing clock recovery and sampling.

One such equalization technique that a receiver circuit can employ is continuous time linear equalization (CTLE), which can be implemented using either passive or active circuits. In a passive circuit implementation, combinations of resistors, capacitors, and/or inductors, can be employed to implement a high-pass transfer function to compensate for loss in the communication channel. While passive CTLE circuit implementation can offer good linearity, it cannot provide gain at the Nyquist frequency for the communication link.

An active circuit CTLE implementation can provide frequency peaking at the Nyquist frequency for the communication link, thereby improving the received signal quality. Amplifier circuits used in such CTLE applications are limited by power supply voltages that can affect their linearity, compressing their output signals. Moreover, the headroom of the transistors included in such amplifier circuits can further degrade the linearity of the amplifier circuits.

The embodiments illustrated in the drawings and described below provide techniques for using controlled positive feedback for an amplifier circuit. By employing positive feedback that is enabled when the output of the amplifier circuit is compressed, a range of linear operation can be increased, thereby improving equalization for a communication channel.

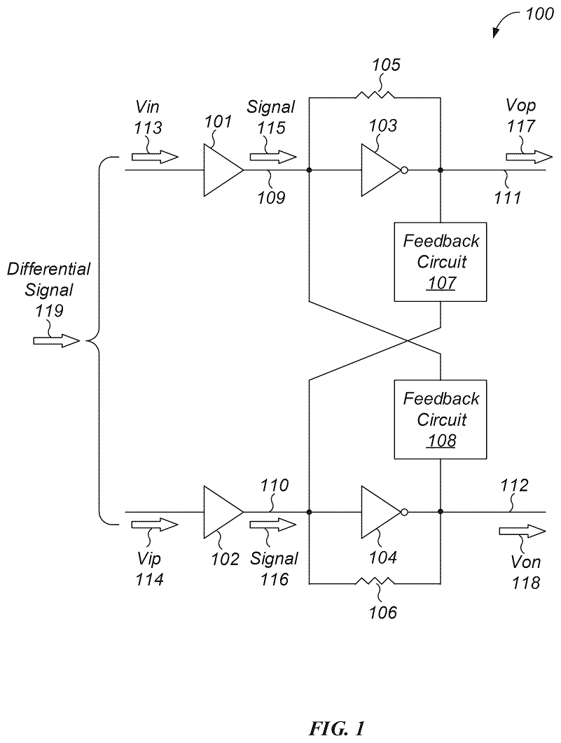

A block diagram of an embodiment of an amplifier circuit is depicted in FIG. 1. As illustrated, amplifier circuit 100 includes amplifier circuits 101-104, resistors 105 and 106, and feedback circuits 107 and 108.

Amplifier circuit 101 is configured to amplify Vin 113 of differential signal 119 to generate signal 115, while amplifier circuit 102 is configured to amplify Vip 114 of differential signal 119 to generate signal 116. It is noted that, in some embodiments, Vip 114 is complementary to Vin 113. In various embodiments, amplifier circuit 101 and amplifier circuit 102 may be implemented using transconductance amplifier circuits or any other suitable type of amplifier circuits.

Amplifier circuit 103 is configured to amplify signal 115 to generate Vop 117, while amplifier circuit 104 is configured to amplify signal 116 to generate Von 118. It is noted that Vop 117 and Von 118 may be complementary and form a differential output signal. In various embodiments, amplifier circuit 103 and amplifier circuit 104 may be implemented using transimpedance amplifier circuits or any other suitable type of amplifier circuits.

Feedback circuit 107 is configured, based on respective voltage levels of Vop 117 and signal 116, to couple node 111 (the output terminal of amplifier circuit 103) to node 110 (the input terminal of amplifier circuit 104). For example, feedback circuit 107 may couple node 111 to node 110 in response to a determination that Vop 117 is greater than signal 116 by at least a threshold value. Alternatively, feedback circuit 107 may couple node 111 to node 110 in response to a determination that signal 116 is greater than Vop 117 by at least a threshold value.

Feedback circuit 108 is configured, based on respective voltage levels of Von 118 and signal 115, to couple node 112 (the output terminal of amplifier circuit 104) to node 109 (the input terminal of amplifier circuit 103). For example, feedback circuit 108 may couple node 112 to node 109 in response to a determination that Von 118 is greater than signal 115 by at least a threshold value. Alternatively, feedback circuit 108 may couple node 112 to node 109 in response to a determination that signal 115 is greater than Von 118 by at least a threshold value.

Resistor 105 is coupled between node 109 and node 111, while resistor 106 is coupled between node 110 and node 112. In various embodiments, resistor 105 may be configured to adjust a gain value of amplifier circuit 103, while resistor 106 may be configured to adjust a gain value of amplifier circuit 104. In some embodiments, resistors 105 and 106 may be implemented using polysilicon, metal, or any suitable material available on a semiconductor manufacturing process.

Although the embodiment in FIG. 1 is depicted as amplifying a differential signal, in other embodiments, similar techniques may be employed for single-ended signals.

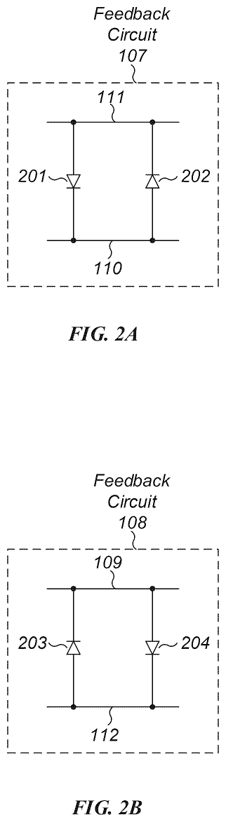

Turning to FIG. 2A, a block diagram of feedback circuit 107 is depicted. As illustrated, feedback circuit 107 includes diodes 201 and 202. An anode of diode 201 is coupled to node 111, and a cathode of diode 201 is coupled to node 110. Similarly, a cathode of diode 202 is coupled to node 111, while an anode of diode 202 is coupled to node 110.

In various embodiments, diodes 201 and 202 are configured to couple node 110 to node 111 based on respective voltage levels of nodes 110 and 111. For example, diode 201 may be configured to activate and conduct current between node 111 and node 110 in response to a determination that a voltage level of node 111 is greater than a voltage level of node 110 by at least a threshold value. In a similar fashion, diode 202 may be configured to activate and conduct current from node 110 to node 111 in response to a determination that the voltage level of node 110 is greater than the voltage level of node 111 by at least a threshold value.

Although diodes 201 and 202 are depicted as single devices, in other embodiments, diodes 201 and 202 may be implemented using any suitable number of diodes coupled together in any suitable parallel and/or series combination. It is noted that by adjusting a number of diodes and/or the physical properties of diodes 201 and 202, the threshold values that determine when nodes 110 and 111 are coupled to one another can be adjusted.

Diodes 201 and 202 may, in various embodiments, be implemented using diode-connected metal-oxide semiconductor field-effect transistors (MOSFETs), fin field-effect transistors (FinFETs), gate-all-around field-effect transistors (GAAFETs), or any other suitable transconductance devices. In other embodiments, diodes 201 and 202 may be implemented using any suitable bipolar junction structure available on a semiconductor manufacturing process.

Turning to FIG. 2B, a block diagram of feedback circuit 108 is depicted. As illustrated, feedback circuit 108 includes diodes 203 and 204. An anode of diode 203 is coupled to node 112, and a cathode of diode 203 is coupled to node 109. Similarly, a cathode of diode 204 is coupled to node 112, while an anode of diode 204 is coupled to node 109.

In various embodiments, diodes 203 and 204 are configured to couple node 109 to node 112 based on respective voltage levels of nodes 109 and 112. For example, diode 203 may be configured to activate and conduct current between node 112 and node 109 in response to a determination that a voltage level of node 112 is greater than a voltage level of node 109 by at least a threshold value. In a similar fashion, diode 204 may be configured to activate and conduct current from node 109 to node 112 in response to a determination that the voltage level of node 109 is greater than the voltage level of node 112 by at least a threshold value.

Although diodes 203 and 204 are depicted as single devices, in other embodiments, diodes 203 and 204 may be implemented using any suitable number of diodes coupled together in any suitable parallel and/or series combination. It is noted that by adjusting a number of diodes and/or the physical properties of diodes 203 and 204, the threshold values that determine when nodes 109 and 112 are coupled to one another can be adjusted.

Diodes 203 and 204 may, in various embodiments, be implemented using diode-connected MOSFETs, FinFETs, GAAFETs, or any other suitable transconductance devices. In other embodiments, diodes 203 and 204 may be implemented using any suitable bipolar junction structure available on a semiconductor manufacturing process.

In some cases, a given amplifier circuit may be used with different communication channels with different electrical characteristics. Some communication channels may not distort transmitted signals as much as others. In cases where the electrical characteristics of a communication channel are within desired ranges, it may be desirable to disable feedback circuits 107 and 108. As described below, some embodiments of feedback circuits 107 and 108 may include switches that can be used to disable the feedback circuits.

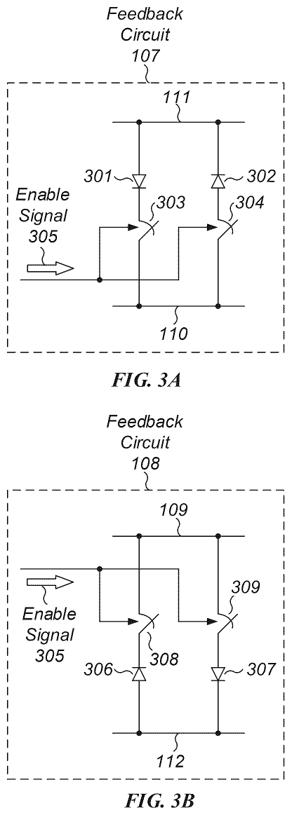

Turning to FIG. 3A, a block diagram of an embodiment of feedback circuit 107 that includes enable switches is depicted. Feedback circuit 107 includes diodes 301 and 302, and switches 303 and 304.

Diode 301 and switch 303 are coupled, in series, between node 111 and node 110, where an anode of diode 301 is coupled to node 111, and a cathode of diode 301 is coupled to switch 303. In various embodiments, switch 303 is configured, in response to an activation of enable signal 305, to couple the cathode of diode 301 to node 110. With switch 303 closed, diode 301 may be configured to couple node 111 to node 110 in response to a determination that a voltage level of node 111 is greater than a voltage level of node 110 by at least a threshold value.

Diode 302 and switch 304 are coupled, in series, between node 111 and node 110, where a cathode of diode 302 is coupled to node 111 and an anode of diode 302 is coupled to switch 304. In various embodiments, switch 304 is configured, in response to an activation of enable signal 305, to couple the anode of diode 302 to node 110. With switch 304 closed, diode 302 may be configured to couple node 111 to node 110 in response to a determination that a voltage level of node 110 is greater than a voltage level of node 111 by at least a threshold value.

Although diodes 301 and 302 are depicted as single devices, in other embodiments, diodes 301 and 302 may be implemented using any suitable number of diodes coupled together in any suitable parallel and/or series combination. It is noted that by adjusting a number of diodes and/or the physical properties of diodes 301 and 302, the threshold values that determine when node 110 and 111 are coupled to one another can be adjusted.

Diodes 301 and 302 may, in various embodiments, be implemented using diode-connected MOSFETs, FinFETs, GAAFETs, or any other suitable transconductance devices. In other embodiments, diodes 301 and 302 may be implemented using any suitable bipolar junction structure available on a semiconductor manufacturing process. Switches 303 and 304 may be implemented using one or more MOSFETs, FinFETs, GAAFETs, or any other suitable transconductance devices.

Turning to FIG. 3B, a block diagram of an embodiment of feedback circuit 108 that includes enable switches is depicted. Feedback circuit 108 includes diodes 306 and 307, and switches 308 and 309.

Diode 306 and switch 308 are coupled, in series, between node 112 and node 109, where an anode of diode 306 is coupled to node 112, and a cathode of diode 306 is coupled to switch 308. In various embodiments, switch 308 is configured, in response to an activation of enable signal 305, to couple the cathode of diode 306 to node 109. With switch 308 closed, diode 306 may be configured to couple node 112 to node 109 in response to a determination that a voltage level of node 112 is greater than a voltage level of node 109 by at least a threshold value.

Diode 307 and switch 309 are coupled, in series, between node 112 and node 109, where a cathode of diode 307 is coupled to node 112 and an anode of diode 307 is coupled to switch 309. In various embodiments, switch 309 is configured, in response to an activation of enable signal 305, to couple the anode of diode 307 to node 109. With switch 309 closed, diode 307 may be configured to couple node 112 to node 109 in response to a determination that a voltage level of node 109 is greater than a voltage level of node 112 by at least a threshold value.

Although diodes 306 and 307 are depicted as single devices, in other embodiments, diodes 306 and 307 may be implemented using any suitable number of diodes coupled together in any suitable parallel and/or series combination. It is noted that by adjusting a number of diodes and/or the physical properties of diodes 306 and 307, the threshold values that determine when nodes 109 and 112 are coupled to one another can be adjusted.

Diodes 306 and 307 may, in various embodiments, be implemented using diode-connected MOSFETs, FinFETs, GAAFETs, or any other suitable transconductance devices. In other embodiments, diodes 306 and 307 may be implemented using any suitable bipolar junction structure available on a semiconductor manufacturing process. Switches 308 and 309 may be implemented using one or more MOSFETs, FinFETs, GAAFETs, or any other suitable transconductance devices.

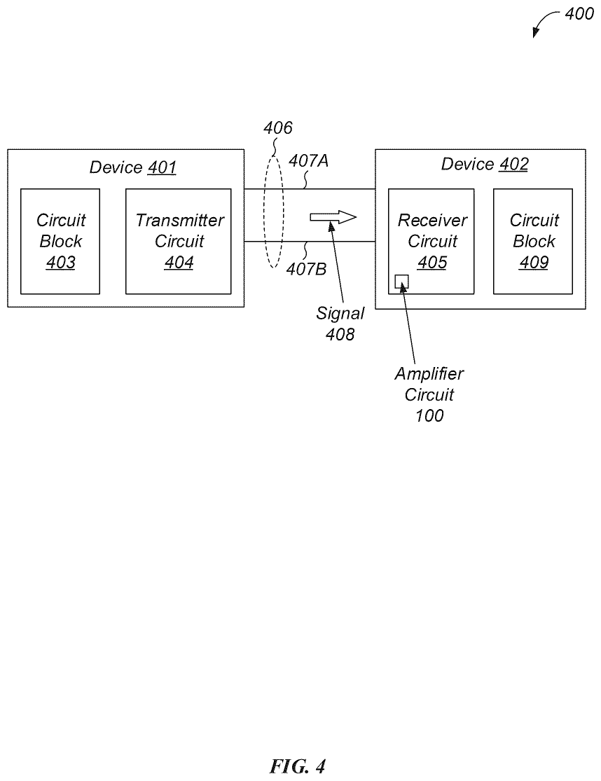

In some computer systems, an amplifier circuit, e.g., amplifier circuit 100 as described above, may be used to implement a receiver circuit for receiving and processing data from a communication channel or link. A block diagram of an embodiment of a computer system that includes two devices coupled to each other via a communication bus is depicted in FIG. 4. As illustrated, computer system 400 includes devices 401 and 402 coupled by communication bus 406.

Device 401 includes circuit block 403 and transmitter circuit 404. In various embodiments, device 401 may be a processor circuit, a processor core, a memory circuit, or any other suitable circuit block that may be included on an integrated circuit in a computer system. It is noted that although device 401 only depicts a single circuit block and a single transmitter circuit, in other embodiments, additional circuit blocks and additional transmitter circuits may be employed.

Transmitter circuit 404 is configured to serially transmit signal 408, via communication bus 406, corresponding to data received from circuit block 403. Such signals may differentially encode one or more bits or symbols such that a difference between the respective voltage levels of wires 407A and 407B, at a particular point in time, correspond to a particular bit or symbol value. In some cases, the generation of signal 408 may include encoding the bits prior to transmission. It is noted that although communication bus 406 is depicted as including two wires, in other embodiments, any suitable number of wires may be employed.

Device 402 includes receiver circuit 405 and circuit block 409. Like device 401, device 402 may be a processor circuit, a processor core, a memory circuit, or any other suitable circuit block configured to receive data from transmitter circuit 404. In various embodiments, receiver circuit 405 may include amplifier circuit 100 as depicted in FIG. 1.

Devices 401 and 402 may, in some embodiments, be fabricated on a common integrated circuit. In other embodiments, devices 401 and 402 may be located on different integrated circuits mounted on a common substrate or circuit board. In such cases, communication bus 406 may include metal or other conductive traces on the substrate or circuit boards. Although only two devices are depicted in computer system 400, in other embodiments, any suitable number of devices may be employed.

To summarize, various embodiments of an amplifier circuit are disclosed. Broadly speaking, the amplifier circuit can include a first amplifier circuit configured to amplify a first signal of a differential signal to generate a first input signal, and include a second amplifier circuit configured to amplify a second signal of the differential signal to generate a second input signal. The amplifier circuit may also include a third amplifier circuit configured to amplify the first input signal to generate a first output signal, and include a fourth amplifier circuit configured to amplify the second input signal to generate a second output signal. The amplifier circuit may include a first feedback signal configured, based on a first voltage level of the first output signal, to couple the first output signal to an input terminal of the fourth amplifier circuit, and include a second feedback circuit configured, based on a second voltage level of the second output signal, to couple the second output signal to an input terminal of the third amplifier circuit.

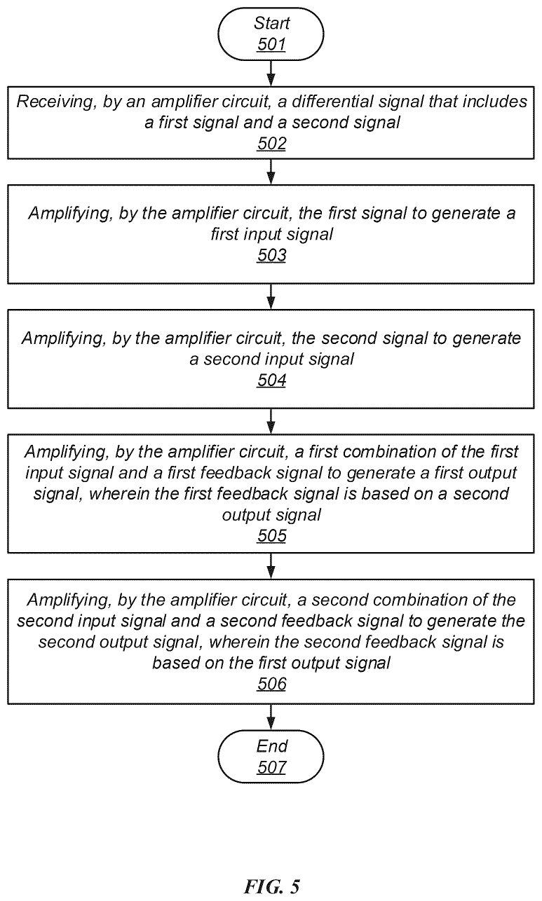

Turning to FIG. 5, a flow diagram depicting an embodiment of a method for operating an amplifier circuit with controlled positive feedback is illustrated. The method, which may be applied to various amplifier circuits, e.g., amplifier circuit 100 as depicted in FIG. 1, begins in block 501.

The method includes receiving, by an amplifier circuit, a differential signal that includes a first signal and a second signal (block 502). In various embodiments, the second signal is complementary to the first signal. In some cases, the method includes receiving, by the amplifier circuit, the differential signal via a communication link.

The method also includes amplifying, by the amplifier circuit, the first signal to generate a first input signal (block 503). In some embodiments, amplifying the first signal includes amplifying, by a first transconductance amplifier circuit, the first signal to generate the first input signal.

The method further includes amplifying, by the amplifier circuit, the second signal to generate a second input signal (block 504). In some embodiments, amplifying the second signal includes amplifying, by a second transconductance amplifier circuit, the second signal to generate the second input signal.

The method also includes amplifying, by the amplifier circuit, a first combination of the first input signal and a first feedback signal to generate a first output signal (block 505). In various embodiments, the first feedback signal is based on a second output signal. In some embodiments, amplifying the first combination includes amplifying, by a first transimpedance amplifier circuit, the first combination to generate the first output signal.

The method further includes amplifying, by the amplifier circuit, a second combination of the second input signal and a second feedback signal to generate the second output signal (block 506). In various embodiments, the second feedback signal is based on the first output signal. In some embodiments, amplifying the second combination includes amplifying, by a second transimpedance amplifier circuit, to generate the second output signal.

In some embodiments, the method may further include coupling a first diode between an output terminal of the first transimpedance amplifier circuit and an input terminal of the second transimpedance amplifier circuit. In such cases, a first anode of the first diode is coupled to the output terminal of the first transimpedance amplifier circuit. Additionally, the method can include coupling a second diode between the output terminal of the first transimpedance amplifier circuit and the input terminal of the second transimpedance amplifier circuit. In such cases, a second anode of the second diode is coupled to the input terminal of the second transimpedance amplifier circuit. In various embodiments, the method may further include decoupling, in response to deactivating an enable signal, a first cathode of the first diode from the input terminal of the second transimpedance amplifier circuit, and decoupling, in response to deactivating the enable signal, the second anode of the second diode from the input terminal of the second transimpedance amplifier circuit.

In some embodiments, the method may further include coupling a first diode between an output terminal of the second transimpedance amplifier circuit and an input terminal of the first transimpedance amplifier circuit. In such cases, a first anode of the first diode is coupled to the output terminal of the second transimpedance amplifier circuit. Additionally, the method can include coupling a second diode between the output terminal of the second transimpedance amplifier circuit and the input terminal of the first transimpedance amplifier circuit. In such cases, a second anode of the second diode is coupled to the input terminal of the first transimpedance amplifier circuit. In various embodiments, the method may further include decoupling, in response to deactivating an enable signal, a first cathode of the first diode from the input terminal of the first transimpedance amplifier circuit, and decoupling, in response to deactivating the enable signal, the second anode of the second diode from the input terminal of the first transimpedance amplifier circuit.

In various embodiments, the method may also include coupling, by a first resistor, a first input terminal of the first transimpedance amplifier circuit to a first output terminal of the first transimpedance amplifier circuit. Additionally, the method may include coupling, by a second resistor, a second input terminal of the second transimpedance amplifier circuit to a second output terminal of the second transimpedance amplifier circuit. The method concludes in block 507.

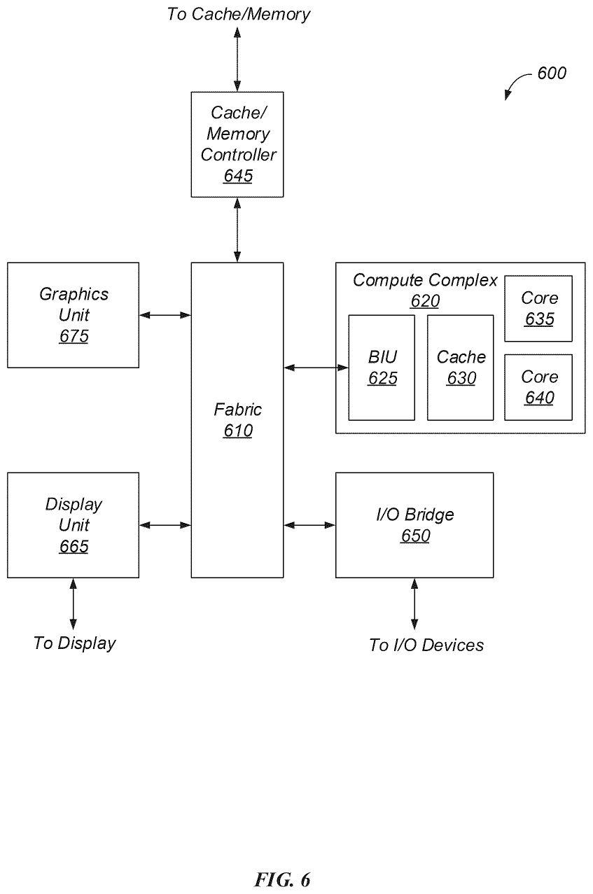

Referring now to FIG. 6, a block diagram illustrating an example embodiment of a device is shown. In some embodiments, elements of device 600 may be included within a system-on-a-chip. In some embodiments, device 600 may be included in a mobile device, which may be battery-powered. Therefore, power consumption by device 600 may be an important design consideration. In the illustrated embodiment, device 600 includes fabric 610, compute complex 620, input/output (I/O) bridge 650, cache/memory controller 645, graphics unit 675, and display unit 665. In some embodiments, device 600 may include other components (not shown) in addition to, or in place of, the illustrated components, such as video processor encoders and decoders, image processing or recognition elements, computer vision elements, etc.

Fabric 610 may include various interconnects, buses, MUX's, controllers, etc., and may be configured to facilitate communication between various elements of device 600. In some embodiments, portions of fabric 610 may be configured to implement various different communication protocols. In other embodiments, fabric 610 may implement a single communication protocol, and elements coupled to fabric 610 may convert from the single communication protocol to other communication protocols internally.

In the illustrated embodiment, compute complex 620 includes bus interface unit (BIU) 625, cache 630, and cores 635 and 640. In various embodiments, compute complex 620 may include various numbers of processors, processor cores, and caches. For example, compute complex 620 may include 1, 2, or 4 processor cores, or any other suitable number. In one embodiment, cache 630 is a set associative L2 cache. In some embodiments, cores 635 and 640 may include internal instruction and data caches. In some embodiments, a coherency unit (not shown) in fabric 610, cache 630, or elsewhere in device 600, may be configured to maintain coherency between various caches of device 600. BIU 625 may be configured to manage communication between compute complex 620 and other elements of device 600. Processor cores, such as cores 635 and 640, may be configured to execute instructions of a particular instruction set architecture (ISA) which may include operating system instructions and user application instructions. These instructions may be stored in a computer readable medium such as a memory coupled to cache/memory controller 645 as discussed below.

As used herein, the term “coupled to” may indicate one or more connections between elements, and a coupling may include intervening elements. For example, in FIG. 6, graphics unit 675 may be described as “coupled to” a memory through fabric 610 and cache/memory controller 645. In contrast, in the illustrated embodiment of FIG. 6, graphics unit 675 is “directly coupled” to fabric 610 because there are no intervening elements.

Cache/memory controller 645 may be configured to manage transfer of data between fabric 610 and one or more caches and memories. For example, cache/memory controller 645 may be coupled to an L3 cache, which may, in turn, be coupled to a system memory. In other embodiments, cache/memory controller 645 may be directly coupled to a memory. In some embodiments, cache/memory controller 645 may include one or more internal caches. Memory coupled to cache/memory controller 645 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 645 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 620 to cause the computing device to perform functionality described herein.

Graphics unit 675 may include one or more processors, e.g., one or more graphics processing units (GPUs). Graphics unit 675 may receive graphics-oriented instructions, such as OPENGL®, Metal®, or DIRECT3D® instructions, for example. Graphics unit 675 may execute specialized GPU instructions or perform other operations based on the received graphics-oriented instructions. Graphics unit 675 may generally be configured to process large blocks of data in parallel, and may build images in a frame buffer for output to a display, which may be included in the device or may be a separate device. Graphics unit 675 may include transform, lighting, triangle, and rendering engines in one or more graphics processing pipelines. Graphics unit 675 may output pixel information for display images. Graphics unit 675, in various embodiments, may include programmable shader circuitry which may include highly parallel execution cores configured to execute graphics programs, which may include pixel tasks, vertex tasks, and compute tasks (which may or may not be graphics-related).

Display unit 665 may be configured to read data from a frame buffer and provide a stream of pixel values for display. Display unit 665 may be configured as a display pipeline in some embodiments. Additionally, display unit 665 may be configured to blend multiple frames to produce an output frame. Further, display unit 665 may include one or more interfaces (e.g., MIPI® or embedded display port (eDP)) for coupling to a user display (e.g., a touchscreen or an external display).

I/O bridge 650 may include various elements configured to implement universal serial bus (USB) communications, security, audio, and low-power always-on functionality, for example. I/O bridge 650 may also include interfaces such as pulse-width modulation (PWM), general-purpose input/output (GPIO), serial peripheral interface (SPI), and inter-integrated circuit (I2C), for example. Various types of peripherals and devices may be coupled to device 600 via I/O bridge 650.

In some embodiments, device 600 includes network interface circuitry (not explicitly shown), which may be connected to fabric 610 or I/O bridge 650. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 600 with connectivity to various types of other devices and networks.

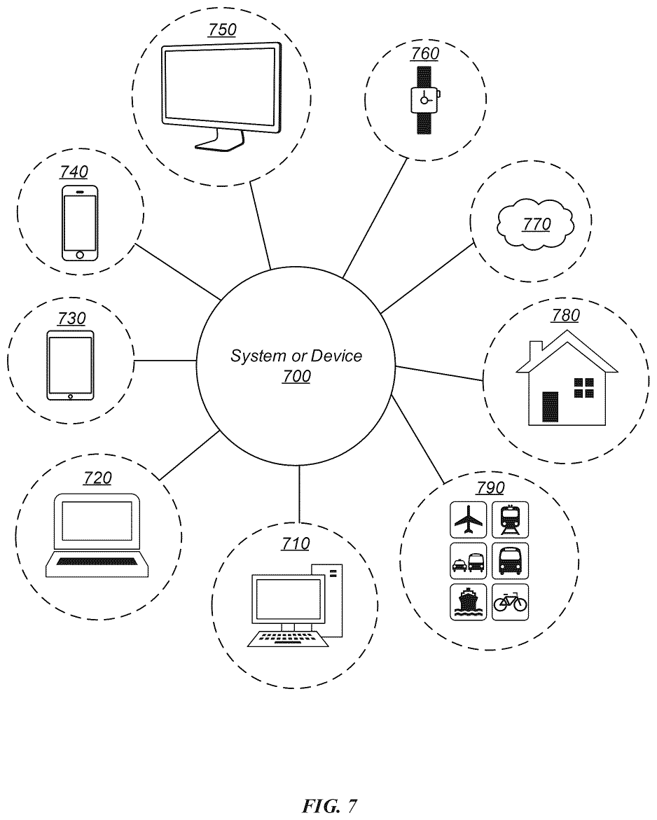

Turning now to FIG. 7, various types of systems that may include any of the circuits, devices, or systems discussed above are illustrated. System or device 700, which may incorporate or otherwise utilize one or more of the techniques described herein, may be utilized in a wide range of areas. For example, system or device 700 may be utilized as part of the hardware of systems such as a desktop computer 710, laptop computer 720, tablet computer 730, cellular or mobile phone 740, or television 750 (or set-top box coupled to a television).

Similarly, disclosed elements may be utilized in a wearable device 760, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 700 may also be used in various other contexts. For example, system or device 700 may be utilized in the context of a server computer system, such as a dedicated server or on shared hardware that implements a cloud-based service 770. Still further, system or device 700 may be implemented in a wide range of specialized everyday devices, including devices 780 commonly found in the home such as refrigerators, thermostats, security cameras, etc. The interconnection of such devices is often referred to as the “Internet of Things” (IoT). Elements may also be implemented in various modes of transportation. For example, system or device 700 could be employed in the control systems, guidance systems, entertainment systems, etc. of various types of vehicles 790.

The applications illustrated in FIG. 7 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

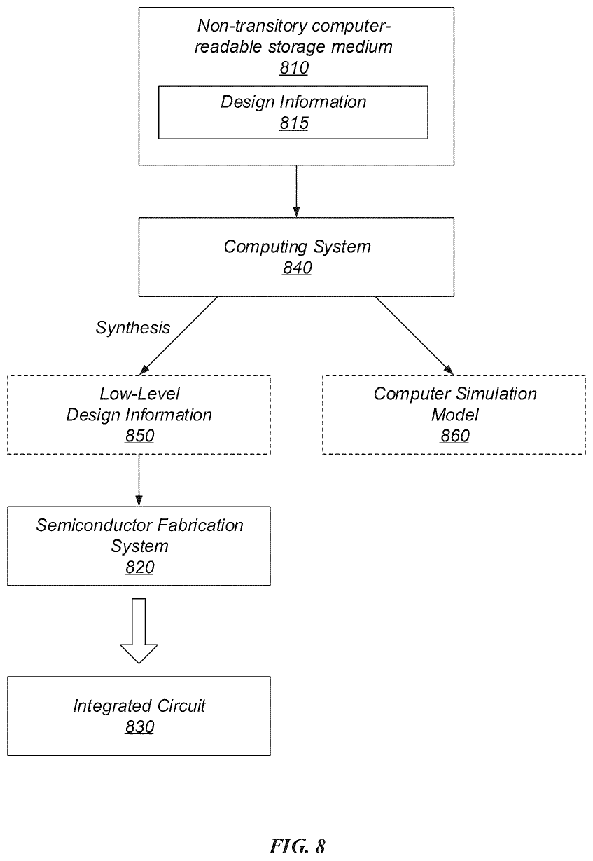

FIG. 8 is a block diagram illustrating an example of a non-transitory computer-readable storage medium that stores design information 815, according to some embodiments. In the illustrated embodiment, computing system 840 is configured to process design information 815. This may include executing instructions included in design information 815, interpreting instructions included in design information 815, compiling, transforming, or otherwise updating design information 815, etc. Therefore, design information 815 controls computing system 840 (e.g., by programming computing system 840) to perform various operations discussed below, in some embodiments.

In the illustrated example, computing system 840 processes design information 815 to generate both computer simulation model of hardware circuit 860 and low-level design information 850. In other embodiments, computing system 840 may generate only one of these outputs, may generate other outputs based on design information 815, or both. Regarding computer simulation model of hardware circuit 860, computing system 840 may execute instructions of a hardware description language that includes register transfer level (RTL) code, behavioral code, structural code, or some combination thereof. The simulation model may perform the functionality specified by design information 815, facilitate verification of the functional correctness of the hardware design, generate power consumption estimates, generate timing estimates, etc.

In the illustrated example, computing system 840 also processes design information 815 to generate low-level design information 850 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 850 (potentially among other inputs), semiconductor fabrication system 820 is configured to fabricate integrated circuit 830 (which may correspond to functionality of the computer simulation model of hardware circuit 860). Note that computing system 840 may generate different simulation models based on design information at various levels of description, including low-level design information 850, design information 815, and so on. The data representing low-level design information 850 and computer simulation model of hardware circuit 860 may be stored on non-transitory computer-readable storage medium 810, or on one or more other media.

In some embodiments, low-level design information 850 controls (e.g., programs) semiconductor fabrication system 820 to fabricate integrated circuit 830. Thus, when processed by the fabrication system, the design information may program the fabrication system to fabricate a circuit that includes various circuitry disclosed herein.

Non-transitory computer-readable storage medium 810 may comprise any of various appropriate types of memory devices or storage devices. Non-transitory computer-readable storage medium 810 may be an installation medium, e.g., a CD-ROM, floppy disks, or tape device; a computer system memory or random access memory such as DRAM, DDR RAM, SRAM, EDO RAM, Rambus RAM, etc. ; a non-volatile memory such as a Flash memory, magnetic media, e.g., a hard drive, or optical storage; registers, or other similar types of memory elements, etc. Non-transitory computer-readable storage medium 810 may include other types of non-transitory memory as well, or combinations thereof. Accordingly, non-transitory computer-readable storage medium 810 may include two or more memory media, which may reside in different locations—for example, in different computer systems that are connected over a network.

Design information 815 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 840, semiconductor fabrication system 820, or both. In some embodiments, design information 815 may also include one or more cell libraries that specify the synthesis, layout, or both of integrated circuit 830. In some embodiments, design information 815 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 830 may, in various embodiments, include one or more custom macrocells, such as memories, analog or mixed-signal circuits, and the like. In such cases, design information 815 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 820 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 820 may also be configured to perform various testing of fabricated circuits for correct operation.

In various embodiments, integrated circuit 830 and computer simulation model of hardware circuit 860 are configured to operate according to a circuit design specified by design information 815, which may include performing any of the functionality described herein. For example, integrated circuit 830 may include any of various elements shown in FIGS. 1-4. Further, integrated circuit 830 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 815. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 815 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 850. Low-level design information 850 may program semiconductor fabrication system 820 to fabricate integrated circuit 830.

* * * *

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a first amplifier circuit configured to amplify a first signal of a differential signal to generate a first input signal;
a second amplifier circuit configured to amplify a second signal of the differential signal to generate a second input signal;
a third amplifier circuit configured to amplify the first input signal to generate a first output signal;
a fourth amplifier circuit configured to amplify the second input signal to generate a second output signal;
a first feedback circuit configured, based on a first voltage level of the first output signal, to couple the first output signal to an input terminal of the fourth amplifier circuit; and
a second feedback circuit configured, based on a second voltage level of the second output signal, to couple the second output signal to an input terminal of the third amplifier circuit.

2. The apparatus of claim 1, wherein the first feedback circuit includes a first diode and a second diode, wherein a first anode of the first diode is coupled to an output terminal of the third amplifier circuit and a second anode of the second diode is coupled to the input terminal of the fourth amplifier circuit, and wherein a first cathode of the first diode is coupled to the input terminal of the fourth amplifier circuit and a second cathode of the second diode is coupled to the output terminal of the third amplifier circuit.

3. The apparatus of claim 1, wherein the second feedback circuit includes a first diode and a second diode, wherein a first anode of the first diode is coupled to an output terminal of the fourth amplifier circuit and a second anode of the second diode is coupled to an input terminal of the third amplifier circuit, and wherein a first cathode of the first diode is coupled to the input terminal of the third amplifier circuit and a second cathode of the second diode is coupled to the output terminal of the fourth amplifier circuit.

4. The apparatus of claim 1, wherein the first feedback circuit includes:
a first diode and a first switch coupled, in series, between an output terminal of the fourth amplifier circuit and an input terminal of the third amplifier circuit such that a first anode of the first diode is coupled to the output terminal of the fourth amplifier circuit, and wherein the first switch is configured, in response to an activation of an enable signal, to couple a first cathode of the first diode to the input terminal of the third amplifier circuit; and
a second diode and a second switch coupled, in series, between the output terminal of the fourth amplifier circuit and the input terminal of the third amplifier circuit such that a second cathode of the second diode is coupled to the output terminal of the fourth amplifier circuit, and wherein the second switch is configured, in response to the activation of the enable signal, to couple a second anode of the second diode to the input terminal of the third amplifier circuit.

5. The apparatus of claim 1, wherein the second feedback circuit includes:
a first diode and a first switch coupled, in series, between an output terminal of the third amplifier circuit and an input terminal of the fourth amplifier circuit such that a first anode of the first diode is coupled to the output terminal of the third amplifier circuit, and wherein the first switch is configured, in response to an activation of an enable signal, to couple a first cathode of the first diode to the input terminal of the fourth amplifier circuit; and
a second diode and a second switch coupled, in series, between the output terminal of the third amplifier circuit and the input terminal of the fourth amplifier circuit such that a second cathode of the second diode is coupled to the output terminal of the third amplifier circuit, and wherein the second switch is configured, in response to the activation of the enable signal, to couple a second anode of the second diode to the input terminal of the fourth amplifier circuit.

6. The apparatus of claim 1, further comprising:
a first resistor coupled between a first input terminal of the third amplifier circuit and a first output terminal of the third amplifier circuit; and
a second resistor coupled between a second input terminal of the fourth amplifier circuit and a second output terminal of the fourth amplifier circuit.

7. A method, comprising:
receiving, by an amplifier circuit, a differential signal that includes a first signal and a second signal;
amplifying, by the amplifier circuit, the first signal to generate a first input signal;
amplifying, by the amplifier circuit, the second signal to generate a second input signal;
amplifying, by the amplifier circuit, a first combination of the first input signal and a first feedback signal to generate an first output signal, wherein the first feedback signal is based on a second output signal; and
amplifying, by the amplifier circuit, a second combination of the second input signal and a second feedback signal to generate the second output signal, wherein the second feedback signal is based on the first output signal.

8. The method of claim 7, wherein amplifying the first signal includes amplifying, by a first transconductance amplifier circuit, the first signal to generate the first input signal, wherein amplifying the second signal includes amplifying, by a second transconductance amplifier circuit, the second signal to generate the second input signal, wherein amplifying the first combination includes amplifying, by a first transimpedance amplifier circuit, the first combination to generate the first output signal, and wherein amplifying the second combination includes amplifying, by a second transimpedance amplifier circuit, the second combination to generate the second output signal.

9. The method of claim 8, further comprising generating the first feedback signal by:
coupling a first diode between an output terminal of the first transimpedance amplifier circuit and an input terminal of the second transimpedance amplifier circuit, wherein a first anode of the first diode is coupled to the output terminal of the first transimpedance amplifier circuit; and
coupling a second diode between the output terminal of the first transimpedance amplifier circuit and the input terminal of the second transimpedance amplifier circuit, wherein a second anode of the second diode is coupled to the input terminal of the second transimpedance amplifier circuit.

10. The method of claim 9, further comprising:
decoupling, in response to deactivating an enable signal, a first cathode of the first diode from the input terminal of the second transimpedance amplifier circuit; and
decoupling, in response to deactivating the enable signal, the second anode of the second diode from the input terminal of the second transimpedance amplifier circuit.

11. The method of claim 8, further comprising generating the second feedback signal by:
coupling a first diode between an output terminal of the second transimpedance amplifier circuit and an input terminal of the first transimpedance amplifier circuit, wherein a first anode of the first diode is coupled to the output terminal of the second transimpedance amplifier circuit; and
coupling a second diode between the output terminal of the second transimpedance amplifier circuit and the input terminal of the first transimpedance amplifier circuit, wherein a second anode of the second diode is coupled to the input terminal of the first transimpedance amplifier circuit.

12. The method of claim 11, further comprising:
decoupling, in response to deactivating an enable signal, a first cathode of the first diode from the input terminal of the first transimpedance amplifier circuit; and
decoupling, in response to deactivating the enable signal, the second anode of the second diode from the input terminal of the first transimpedance amplifier circuit.

13. The method of claim 8, further comprising:
coupling, by a first resistor, a first input terminal of the first transimpedance amplifier circuit and a first output terminal of the first transimpedance amplifier circuit; and
coupling, by a second resistor, a second input terminal of the second transimpedance amplifier circuit and a second output terminal of the second transimpedance amplifier circuit.

14. A system, comprising:
a first device configured to transmit, via a communication link, a differential signal encoding a plurality of data symbols, that includes a first signal and a second signal; and
a second device coupled to the communication link, wherein the second device includes an amplifier circuit configured to:
receive the differential signal;
amplify the first signal to generate a first input signal;
amplify the second signal to generate a second input signal;
amplify a first combination of the first input signal and a first feedback signal to generate a first output signal, wherein the first feedback signal is based on a second output signal; and
amplify a second combination of the second input signal and a second feedback signal to generate the second output signal, wherein the second feedback signal is based on the first output signal.

15. The system of claim 14, wherein the amplifier circuit includes:
a first transconductance amplifier circuit configured to amplify the first signal to generate the first input signal;
a second transconductance amplifier circuit configured to amplify the second signal to generate the second input signal;
a first transimpedance amplifier circuit configured to amplify the first combination to generate the first output signal; and
a second transimpedance amplifier circuit configured to amplify the second combination to generate the second output signal.

16. The system of claim 15, wherein the amplifier circuit further includes:
a first diode coupled between an output terminal of the first transimpedance amplifier circuit and an input terminal of the second transimpedance amplifier circuit, wherein a first anode of the first diode is coupled to the output terminal of the first transimpedance amplifier circuit; and
a second diode coupled between the output terminal of the first transimpedance amplifier circuit and the input terminal of the second transimpedance amplifier circuit, wherein a second anode of the second diode is coupled to the input terminal of the second transimpedance amplifier circuit.

17. The system of claim 16, wherein the amplifier circuit further includes:
a first switch configured, in response to a deactivation of an enable signal, to decouple a first cathode of the first diode from the input terminal of the second transimpedance amplifier circuit; and
a second switch configured to, in response to the deactivation of the enable signal, decouple the second anode of the second diode from the input terminal of the second transimpedance amplifier circuit.

18. The system of claim 15, wherein the amplifier circuit further includes:
a first diode coupled between an output terminal of the second transimpedance amplifier circuit and an input terminal of the first transimpedance amplifier circuit, wherein a first anode of the first diode is coupled to the output terminal of the second transimpedance amplifier circuit; and
a second diode coupled between the output terminal of the second transimpedance amplifier circuit and the input terminal of the first transimpedance amplifier circuit, wherein a second anode of the second diode is coupled to the input terminal of the first transimpedance amplifier circuit.

19. The system of claim 18, wherein the amplifier circuit further includes:
a first switch configured, in response to a deactivation of an enable signal, to decouple a first cathode of the first diode from the input terminal of the first transimpedance amplifier circuit; and
a second switch configured, in response to the deactivation of the enable signal, to decouple the second anode of the second diode from the input terminal of the first transimpedance amplifier circuit.

20. The system of claim 15, wherein the amplifier circuit further includes:
a first resistor coupled between a first input terminal of the first transimpedance amplifier circuit and a first output terminal of the first transimpedance amplifier circuit; and
a second resistor coupled between a second input terminal of the second transimpedance amplifier circuit and a second output terminal of the second transimpedance amplifier circuit.
